(19) United States
(12) Patent Application Publication
(10) Pub. No.: US 2026/0155631 A1
(43) Pub. Date: Jun. 4, 2026

(54) SEMICONDUCTOR LAYERED BODY, METHOD OF MANUFACTURING SEMICONDUCTOR LAYERED BODY, AND OPTICAL SEMICONDUCTOR DEVICE

(71) Applicant: SUMITOMO ELECTRIC INDUSTRIES, LTD., Osaka (JP)

(72) Inventors: Takahiro YASUNAMI, Osaka (JP); Kenshi TAKADA, Osaka (JP)

(73) Assignee: SUMITOMO ELECTRIC INDUSTRIES, LTD., Osaka (JP)

(21) Appl. No.: 19/404,288

(22) Filed: Dec. 1, 2025

(30) Foreign Application Priority Data
Dec. 4, 2024 (JP) 2024-210946

(51) Int. Cl. H01S 5/343

(52) U.S. Cl. CPC H01S 5/34313

(57) ABSTRACT

A semiconductor layered body according to the present disclosure includes a first semiconductor layer formed of a III-V compound semiconductor, and a p-type InGaAs layer stacked on the first semiconductor layer and containing carbon as an impurity that generates majority carriers. The p-type InGaAs layer has a resistivity of 2.0×10⁻³ Ωcm or less.

### CROSS REFERENCE TO RELATED APPLICATIONS

This application claims priority based on Japanese Patent Application No. 2024-210946 filed on Dec. 4, 2024, and the entire contents of the Japanese patent application are incorporated herein by reference.

### TECHNICAL FIELD

The present disclosure relates to a semiconductor layered body, a method of manufacturing a semiconductor layered body, and an optical semiconductor device.

### BACKGROUND

A semiconductor layered body having a structure in which a semiconductor layer formed of a III-V compound semiconductor is stacked on a substrate formed of a III-V compound semiconductor is used in a semiconductor device such as an optical semiconductor device and a semiconductor electronic device. Since the semiconductor device is operated based on current, a metal electrode for flowing the current is formed on a surface of the semiconductor layered body. In this case, a contact layer is required to reduce contact resistance between the electrode and the semiconductor layered body, and a high-density semiconductor layer having a high carrier density is used as the contact layer to reduce the contact resistance. In addition, in order to form a tunnel junction region with a reduced operating voltage in a pn junction in which a p-type semiconductor layer and an n-type semiconductor layer are bonded, the high-density semiconductor layer having a high carrier density is required.

For example, in a semiconductor layered body in which a semiconductor layer is stacked on a substrate formed of indium phosphide (InP), a semiconductor layer (InGaAs layer) formed of indium gallium arsenide (InGaAs), which can be lattice-matched to InP, is used as the high-density semiconductor layer. Here, when a p-type InGaAs layer is fabricated, carbon (C) capable of being doped at a high concentration is attracting attention as an impurity serving as an acceptor. By using carbon as an acceptor, a p-type InGaAs layer having a carrier density of about 1.8×10¹⁹/cm³ to 7.0×10¹⁹/cm³ is fabricated (see, for example, Patent Literature 1: Japanese Unexamined Patent Application Publication No. 2005-086135, Patent Literature 2: Japanese Unexamined Patent Application Publication No. 2007-180115, and Non-patent Literature 1: K. Hong et al, “Heavily carbon doped InGaAs lattice matched to InP grown by LP-MOCVD using TMIn, TMGa and liquid CCl/sub 4/”, May 1995, IEEE).

### SUMMARY

A semiconductor layered body according to the present disclosure includes a first semiconductor layer formed of a III-V compound semiconductor, and a p-type InGaAs layer stacked on the first semiconductor layer and containing carbon as an impurity that generates majority carriers. The p-type InGaAs layer has a resistivity of 2.0×10⁻³ Ωcm or less.

### BRIEF DESCRIPTION OF THE DRAWINGS

FIG. 1 is a schematic cross-sectional view schematically showing a structure of a semiconductor layered body according to an embodiment.

FIG. 2 is a flow chart outlining a method of manufacturing a semiconductor layered body according to an embodiment.

FIG. 3 is a schematic diagram schematically showing a structure of a semiconductor laser that is an optical semiconductor device according to an embodiment.

FIG. 4 is a graph showing a carrier density and a carrier mobility of each sample.

### DETAILED DESCRIPTION

The p-type InGaAs layer with a high carrier density reduces the contact resistance with the electrode when used as the contact layer, and further reduces the operating voltage when used as the semiconductor layer forming a tunnel junction. Note that, in order to reduce the contact resistance and the operating voltage, it is necessary to increase not only the carrier density but also a carrier mobility of the p-type InGaAs layer.

Thus, it is an object of the present disclosure to provide a semiconductor layered body, a method of manufacturing a semiconductor layered body, and an optical semiconductor device, each of which includes a p-type InGaAs layer having a high carrier density and a high carrier mobility.

### DESCRIPTION OF EMBODIMENTS OF PRESENT DISCLOSURE

First, embodiments of the present disclosure will be listed and described.
(1) A semiconductor layered body according to the present disclosure includes a first semiconductor layer formed of a III-V compound semiconductor, and a p-type InGaAs layer stacked on the first semiconductor layer and containing carbon as an impurity that generates majority carriers. The p-type InGaAs layer has a resistivity of 2.0×10⁻³ Ωcm or less.

In the present disclosure, the expression “formed of (a certain element)” means formed using a certain element, and may include an element other than the certain element.

In the semiconductor layered body according to the present disclosure, the resistivity of the p-type InGaAs layer is 2.0×10⁻³ Ωcm or less, indicating low resistivity. Thus, a density of majority carriers (referred to as “carrier density” in the present disclosure) is high, and a mobility of the majority carriers (referred to as “carrier mobility” in the present disclosure) is high in the p-type InGaAs layer. Thus, according to the present disclosure, the semiconductor layered body including the p-type InGaAs layer having a high carrier density and a high carrier mobility is provided.
(2) In the semiconductor layered body according to the above (1), a mobility of the majority carriers in the p-type InGaAs layer may be 40 cm²/Vs or more. According to such a semiconductor layered body, the resistivity of the p-type InGaAs layer is further reduced.
(3) In the semiconductor layered body according to the above (1) or (2), a density of the majority carriers in the p-type InGaAs layer may be 8.0×10¹⁹ cm⁻³ or more. According to such a semiconductor layered body, the resistivity of the p-type InGaAs layer is further reduced.
(4) In the semiconductor layered body according to any one of the above (1) to (3), an activation ratio of the impurity in the p-type InGaAs layer may be 50% or more. According to such a semiconductor layered body, since the amount of non-activated carbon is reduced in the carbon contained as an impurity in the p-type InGaAs layer, the quality of the p-type InGaAs layer becomes good, and the reliability of the p-type InGaAs layer is improved. In addition, the non-activated carbon contained in the p-type InGaAs layer causes a decrease in the carrier mobility. Thus, the carrier mobility of the p-type InGaAs layer is improved by the reduction of the non-activated carbon.
(5) An optical semiconductor device according to the present disclosure includes a semiconductor layered body including a first semiconductor layer formed of a III-V compound semiconductor and a p-type InGaAs layer stacked on the first semiconductor layer and an electrode disposed in contact with the p-type InGaAs layer of the semiconductor layered body. The p-type InGaAs layer contains carbon as an impurity that generates majority carriers. The p-type InGaAs layer has a resistivity of 2.0×10⁻³ Ωcm or less.

The optical semiconductor device according to the present disclosure includes the semiconductor layered body according to the present disclosure, and the p-type InGaAs layer having a low resistivity, a high carrier density and a high carrier mobility is in contact with the electrode serving as an anode as a p-type contact layer. Thus, the contact resistance of the p-type contact layer with respect to the electrode is reduced. Thus, according to the present disclosure, the optical semiconductor device having a low contact resistance is provided.
(6) A method of manufacturing a semiconductor layered body according to the present disclosure includes preparing a substrate formed of a III-V compound semiconductor, stacking a semiconductor layer formed of a III-V compound semiconductor on the substrate by epitaxial growth, and performing heat treatment on the semiconductor layer. The stacking the semiconductor layer includes stacking a p-type InGaAs layer containing carbon as an impurity that generates majority carriers by a chemical vapor deposition using an organometallic gas as a raw material for each of indium, gallium, and arsenic. In the stacking the p-type InGaAs layer, the raw material for arsenic is tertiary butyl arsine, and a temperature of the substrate is 500° C. or less. In the performing the heat treatment on the semiconductor layer, the semiconductor layer is heated at a temperature of 500° C. or less in an inert gas atmosphere.

In the method of manufacturing the semiconductor layered body according to the present disclosure, a source gas for arsenic in the stacking the p-type InGaAs layer is tertiary butyl arsine. Tertiary butyl arsine is an organometallic compound, and is less likely to generate hydrogen by thermal decomposition. Thus, the inactivation of carbon is reduced, since, according to the method of manufacturing the semiconductor layered body of the present disclosure, the incorporation of hydrogen into the p-type InGaAs layer is reduced during stacking of the p-type InGaAs layer and bonding of hydrogen to carbon as an impurity is reduced.

Further, in the method of manufacturing the semiconductor layered body according to the present disclosure, the temperature of the substrate in the stacking the p-type InGaAs layer is 500° C. or less. Carbon as an impurity is an amphoteric element, and in order to dope carbon at a high concentration, it is necessary to stack the p-type InGaAs layer at a low temperature. Also, carbon tends to be inactivated at a high temperature. According to the method of manufacturing the semiconductor layered body according to the present disclosure, since the temperature of the substrate at the time of stacking the p-type InGaAs layer is a low temperature of 500° C. or less, carbon is doped at a high concentration, and the inactivation of carbon is reduced. In addition, in order to increase the doping amount of carbon, it is necessary to stack the p-type InGaAs layer at a low temperature, but tertiary butyl arsine, which is the source gas for arsenic, has a low decomposition temperature and is thermally decomposed at a low temperature of 500° C. or less. Thus, the p-type InGaAs layer can be grown with good crystallinity even at a low temperature of 500° C. or less, and a high-quality p-type InGaAs layer is stacked by low-temperature crystal growth.

Further, in the method of manufacturing the semiconductor layered body according to the present disclosure, the heat treatment of the semiconductor layer in the performing the heat treatment on the semiconductor layer is performed in an inert gas atmosphere and at a heating temperature of 500° C. or less. By performing the heat treatment on the semiconductor layer in an inert gas atmosphere in which hydrogen does not exist, the influence of inactivation of carbon as an impurity is reduced. Also, carbon tends to be inactivated at a high temperature. Thus, according to the method of manufacturing the semiconductor layered body according to the present disclosure, the temperature during the heat treatment is a low temperature of 500° C. or less, so that the inactivation of carbon is reduced.

As described above, according to the method of manufacturing the semiconductor layered body according to the present disclosure, the activation ratio of carbon contained as an impurity in the p-type InGaAs layer is improved, and thus the semiconductor layered body including the p-type InGaAs layer having a high carrier density and a high carrier concentration and having a low resistivity is provided. In addition, according to the method of manufacturing the semiconductor layered body according to the present disclosure, the activation ratio of carbon contained as an impurity in the p-type InGaAs layer is high, and the amount of non-activated carbon is reduced. Thus, the semiconductor layered body having a highly reliable p-type InGaAs layer is provided.

In the method of manufacturing the semiconductor layered body according to the present disclosure, the source gas for arsenic in the stacking the p-type InGaAs layer is tertiary butyl arsine, and tertiary butyl arsine is thermally decomposed at a low temperature of 500° C. or less. Thus, according to the method of manufacturing the semiconductor layered body according to the present disclosure, the p-type InGaAs layer can be stacked even at a low temperature of 500° C. or less, and the crystallinity of the p-type InGaAs layer can be improved by the stacking at a low temperature.

### DETAILS OF EMBODIMENTS OF PRESENT DISCLOSURE

Next, embodiments of a semiconductor layered body, a method of manufacturing a semiconductor layered body, and an optical semiconductor device according to the present disclosure will be described with reference to the drawings. In the following description, the same or corresponding parts in the drawings are denoted by the same reference numerals, and the description thereof will not be repeated.

### (Description of Structure of Semiconductor Layered Body)

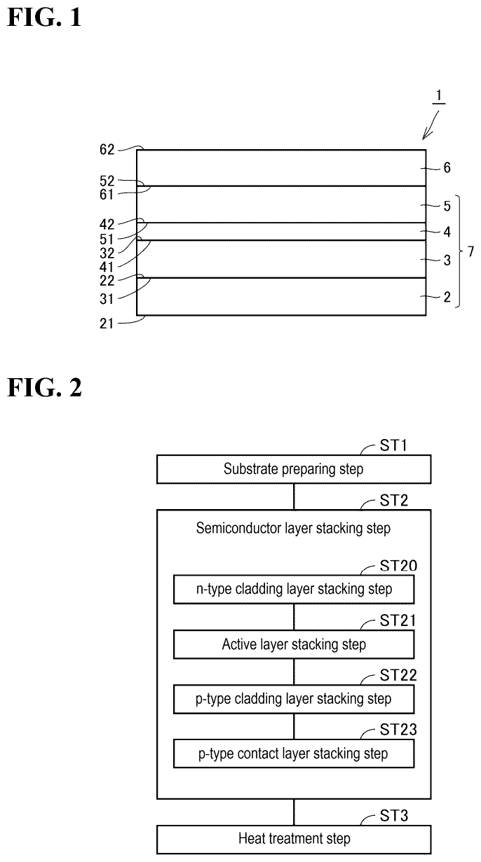

FIG. 1 is a schematic cross-sectional view schematically showing a structure of a semiconductor layered body 1 according to an embodiment of the present disclosure. Referring to FIG. 1, the semiconductor layered body 1 includes a substrate 2, an n-type cladding layer 3, an active layer 4, a p-type cladding layer 5, and a p-type contact layer 6. The semiconductor layered body 1 has a double heterostructure in which the substrate 2, the n-type cladding layer 3, the active layer 4, the p-type cladding layer 5, and the p-type contact layer 6 are stacked in this order.

In the semiconductor layered body 1 according to the present embodiment, the substrate 2, the n-type cladding layer 3, the active layer 4, and the p-type cladding layer 5 are a first semiconductor layer 7 formed of a III-V compound semiconductor. The p-type contact layer 6 is a p-type InGaAs layer which is stacked on the first semiconductor layer 7 and contains carbon as an impurity that generates majority carriers.

The substrate 2 has a pair of main surfaces, a first main surface 21 and a second main surface 22, which are parallel to each other and located at both ends in a film thickness direction. The film thickness of the substrate 2 may be, for example, greater than 0 μm and 700 μm or less. In the present disclosure, the term “film thickness” means the minimum value of the film thickness unless otherwise specified. The diameter of the substrate 2 may be, for example, 50 mm or more, and may be, for example, 3 inches. The diameter of the substrate 2 may be 80 mm or more (for example, 4 inches) from the viewpoint of improving the production efficiency and yield of a semiconductor device such as an optical semiconductor device using the semiconductor layered body 1. The diameter of the substrate 2 may further be 100 mm or more (for example, 5 inches), and may further be 130 mm or more (for example, 6 inches).

The substrate 2 is formed of a III-V compound semiconductor. As the III-V compound semiconductor forming the substrate 2, for example, InP whose conductivity type is n-type may be adopted. As an impurity serving as a donor for generating majority carriers in the substrate 2, for example, sulfur (S) or silicon (Si) may be adopted. The substrate 2 has a higher impurity concentration than the n-type cladding layer 3, and thus has a higher carrier density than the n-type cladding layer 3. The carrier density of the substrate 2 may be, for example, 1.0×10¹⁷ cm⁻³ to 1.0×10¹⁹ cm⁻³.

The carrier density means the density of majority carriers (p-type carriers (holes) or n-type carriers (electrons)) generated by impurities excluding non-activated impurities among impurities included in the semiconductor.

The carrier density can be measured through C-V (capacitance-voltage) measurement, Hall measurement (a method of measuring a Hall effect), or the like. The carrier density can be measured using, for example, the ECV-pro, an electrochemical capacitance-voltage (ECV) measuring device manufactured by Nanometrics Inc.

The n-type cladding layer 3 is a semiconductor layer whose conductivity type is n-type. The n-type cladding layer 3 is formed of a III-V compound semiconductor. As the III-V compound semiconductor forming the n-type cladding layer 3, for example, InP whose conductivity type is n-type may be adopted. As an impurity serving as a donor in the n-type cladding layer 3, for example, sulfur or silicon may be adopted. The carrier density of the n-type cladding layer 3 may be, for example, 1.0×10¹⁷ cm⁻³ to 1.0×10¹⁹ cm⁻³.

The n-type cladding layer 3 has a pair of main surfaces, a first main surface 31 and a second main surface 32, which are parallel to each other and located at both ends in the film thickness direction. The film thickness of the n-type cladding layer 3 may be, for example, 0.1 μm to 10 μm. The n-type cladding layer 3 is disposed such that the first main surface 31 is in contact with the second main surface 22 of the substrate 2. The n-type cladding layer 3 is stacked on the second main surface 22 of the substrate 2 by, for example, epitaxial growth.

The active layer 4 has a structure in which a plurality of semiconductor layers, each formed of a III-V compound semiconductor, are stacked. The active layer 4 may be a separate confinement heterostructure multiple quantum well (SCH-MQW) including an InGaAs layer and an indium gallium arsenide phosphide (InGaAsP) layer, for example.

The active layer 4 has a pair of main surfaces, a first main surface 41 and a second main surface 42, which are parallel to each other and located at both ends in the film thickness direction. The film thickness of the active layer 4 may be, for example, 0.1 μm to 1.0 μm. The active layer 4 is disposed such that the first main surface 41 is in contact with the second main surface 32 of the n-type cladding layer 3. The active layer 4 is stacked on the second main surface 32 of the n-type cladding layer 3 by, for example, epitaxial growth.

The p-type cladding layer 5 is a semiconductor layer whose conductivity type is p-type. The p-type cladding layer 5 is formed of a III-V compound semiconductor. As the III-V compound semiconductor forming the p-type cladding layer 5, for example, InP or InGaAs, both of which have p-type conductivity, may be adopted. As an impurity serving as an acceptor for generating majority carriers in the p-type cladding layer 5, for example, zinc (Zn) or carbon (C) may be adopted. The carrier density of the p-type cladding layer 5 may be, for example, 1.0×10¹⁷ cm⁻³ to 1.0×10¹⁹ cm⁻³.

The p-type cladding layer 5 has a pair of main surfaces, a first main surface 51 and a second main surface 52, which are parallel to each other and located at both ends in the film thickness direction. The film thickness of the p-type cladding layer 5 may be, for example, 0.1 μm to 10.0 μm. The p-type cladding layer 5 is disposed such that the first main surface 51 is in contact with the second main surface 42 of the active layer 4. The p-type cladding layer 5 is stacked on the second main surface 42 of the active layer 4 by, for example, epitaxial growth.

The p-type contact layer 6 is a semiconductor layer whose conductivity type is p-type. The p-type contact layer 6 is a semiconductor layer formed of InGaAs which is a III-V compound semiconductor that has a low band gap and can be lattice-matched to InP. In the p-type InGaAs layer forming the p-type contact layer 6, a content of indium may be, for example, 30% by mass to 40% by mass. A content of gallium may be, for example, 15% by mass to 25% by mass. A content of arsenic may be, for example, 40% by mass to 50% by mass.

The p-type contact layer 6 has a pair of main surfaces, a first main surface 61 and a second main surface 62, which are parallel to each other and located at both ends in the film thickness direction. The film thickness of the p-type contact layer 6 may be, for example, 0.01 μm to 1.0 μm. The p-type contact layer 6 is disposed such that the first main surface 61 is in contact with the second main surface 52 of the p-type cladding layer 5. The p-type contact layer 6 is stacked on the second main surface 52 of the p-type cladding layer 5 by, for example, epitaxial growth. A first electrode 11 (anode) described later is in contact with the second main surface 62 of the p-type contact layer 6.

The p-type contact layer 6 contains carbon as an impurity serving as an acceptor. The p-type contact layer 6 is doped with carbon at a high concentration. The concentration of the doped carbon is higher than the concentration of the doped impurity in each of the substrate 2, the n-type cladding layer 3, and the p-type cladding layer 5. The concentration of the doped carbon may be, for example, 1.0×10²⁰ cm⁻³ or more, and may be 5.0×10²⁰ cm⁻³ or more from the viewpoint of increasing a carrier density of the p-type contact layer 6. The concentration of the doped carbon may be, for example, 10.0×1020 cm⁻³ or less from the viewpoint of preventing a decrease in the activation ratio of carbon, improving the quality of the p-type contact layer 6, and increasing a carrier mobility of the p-type contact layer 6.

The concentration of the impurity (carbon) in the p-type contact layer 6 can be measured by secondary ion mass spectrometry (SIMS), glow discharge mass spectrometry (GDMS), or the like.

The carrier density of the p-type contact layer 6 may be, for example, 8.0×10¹⁹ cm⁻³ or more, and may further be 5.0×1020 cm⁻³ or more. The carrier density of the p-type contact layer 6 may be, for example, 10.0×10²⁰ cm⁻³ or less. When the carrier density of the p-type contact layer 6 is 8.0×10¹⁹ cm⁻³ or more, the contact resistance of the p-type contact layer 6 with respect to the first electrode 11 can be reduced.

The carrier mobility of the p-type contact layer 6 may be, for example, 40 cm²/Vs or more, may further be 45 cm²/Vs or more, and may further be 48 cm²/Vs or more. The carrier mobility of the p-type contact layer 6 may be, for example, 50 cm²/Vs or less. The carrier mobility can be measured by, for example, Hall measurement. When the carrier mobility of the p-type contact layer 6 is 40 cm²/Vs or more, the contact resistance of the p-type contact layer 6 with respect to the first electrode 11 can be reduced.

An activation ratio of the impurity (carbon) in the p-type contact layer 6 may be, for example, 50% or more, may further be 70% or more, and may further be 90% or more. The activation ratio is defined as (carrier density)/(concentration of doped impurity (carbon))×100(%). The activation ratio of the impurity (carbon) in the p-type contact layer 6 is set to 50% or more to reduce the non-activated carbon, thereby improving the quality of the p-type contact layer 6. As a result, the reliability of the p-type contact layer 6 can be improved. In addition, since the non-activated carbon contained in the p-type contact layer 6 causes a decrease in the carrier mobility, the carrier mobility of the p-type contact layer 6 can be improved by reducing the non-activated carbon.

The p-type contact layer 6 has a low resistivity due to the increased carrier density, carrier mobility, and activation ratio of the impurity (carbon). The resistivity of the p-type contact layer 6 is 2.0×10⁻³ Ωcm or less. The resistivity of the p-type contact layer 6 may be 1.6×10⁻³ Ωcm or less, and may be 1.5×10⁻³ Ωcm or less, from the viewpoint of further increasing the conductivity of the p-type contact layer 6. The resistivity of the p-type contact layer 6 can be measured by a four-probe method, a two-probe method, or the like.

When the resistivity of the p-type contact layer 6 is 2.0×10⁻³ Ωcm or less, the carrier density and the carrier mobility of the p-type contact layer 6 may be, for example, 8.0×10¹⁹ cm⁻³ or more and 40 cm²/Vs or more, respectively. Furthermore, the carrier density may be 8.0×10¹⁹ cm⁻³ or more and the carrier mobility may be 48 cm²/Vs or more, or the carrier density may be 1.0×10²⁰ cm⁻³ or more and the carrier mobility may be 40 cm²/Vs or more.

In the semiconductor layered body 1 according to the present embodiment, the resistivity of the p-type InGaAs layer forming the p-type contact layer 6 is 2.0×10⁻³ Ωcm or less, indicating low resistivity. Thus, the p-type contact layer 6 has a high carrier density and a high carrier mobility. Thus, the contact resistance of the p-type contact layer 6 with respect to an electrode serving as an anode (hereinafter referred to as “first electrode”) 11 can be reduced, and the first electrode 11 can be in ohmic contact with the p-type contact layer 6.

In the semiconductor layered body 1 according to the present embodiment, the concentration of the doped carbon in the p-type InGaAs layer forming the p-type contact layer 6 is as high as 1.0×10²⁰ cm⁻³ or more, and the activation ratio of carbon is as high as 50% or more. Thus, the resistivity of the p-type contact layer 6 can be reduced by increasing the carrier density of the p-type contact layer 6. In addition, the carrier mobility of the p-type contact layer 6 is increased by reducing the non-activated carbon contained in the p-type contact layer 6, and the resistivity of the p-type contact layer 6 can be reduced. In addition, since the quality of the p-type contact layer 6 can be improved, the reliability of the p-type contact layer 6 can be improved.

As described above, according to the present disclosure, the semiconductor layered body 1 is provided which includes the p-type contact layer 6 having a low contact resistance with respect to the electrode serving as the anode and in which the p-type contact layer 6 has a high reliability.

### (Description of Method of Manufacturing Semiconductor Layered Body)

Next, an example of a method of manufacturing the semiconductor layered body according to the present embodiment will be described with reference to FIG. 2. FIG. 2 is a block diagram showing a procedure of the method of manufacturing the semiconductor layered body according to the present embodiment. Referring to FIG. 2, the method of manufacturing the semiconductor layered body according to the present embodiment includes a substrate preparing step of preparing the substrate 2 as a ST1 step, a semiconductor layer stacking step of stacking the semiconductor layers 3 to 6 on or above the substrate 2 as a ST2 step, and a heat treatment step of performing heat treatment on the semiconductor layers 3 to 6 stacked on or above the substrate 2 as a ST3 step.

First, in the ST1 step, the substrate 2 formed of n-type InP which is a III-V compound semiconductor is prepared. Specifically, the substrate 2 formed of InP is obtained by slicing an ingot formed of InP. The substrate 2 is subjected to processes such as polishing and cleaning, so that the flatness and cleanliness of the second main surface 22 are ensured.

Next, in the ST2 step, the semiconductor layers 3 to 6 each formed of a III-V compound semiconductor are stacked on or above the substrate 2 prepared in the ST1 step by epitaxial growth. As the semiconductor layers 3 to 6, the n-type cladding layer 3, the active layer 4, the p-type cladding layer 5, and the p-type contact layer 6 are sequentially stacked on the second main surface 22 of the substrate 2. As a method of the epitaxial growth, for example, a vapor deposition method such as metal organic chemical vapor deposition is adopted. The semiconductor layers 3 to 6 are stacked, for example, as follows. The substrate 2 is placed in a growth furnace, and the substrate 2 is heated to a predetermined temperature by a heater. In this state, the temperature, pressure, and the like in the growth furnace are appropriately adjusted while an appropriate source gas is supplied into the growth furnace, and the semiconductor is grown to a predetermined film thickness, whereby the semiconductor layers 3 to 6 are sequentially stacked on or above the substrate 2.

In a ST20 step of stacking the n-type cladding layer 3 in the ST2 step, a semiconductor layer formed of, for example, n-type InP is stacked on the second main surface 22 of the substrate 2. In the ST20 step, trimethylindium (TMIn) of an organometallic gas is adopted as a source gas for indium, for example. As a source gas for phosphorus, tertiary butyl phosphine (TBP) of an organometallic gas is adopted, for example. As a donor for generating majority carriers, sulfur is adopted, for example.

In a ST21 step of stacking the active layer 4 in the ST2 step, a semiconductor layer including, for example, an InGaAs layer and an InGaAsP layer is stacked on the second main surface 32 of the n-type cladding layer 3. In the ST21 step, trimethylindium of an organometallic gas is adopted as a source gas for indium, for example. As a source gas for gallium, for example, triethylgallium (TEGa) of an organometallic gas is adopted. As a source gas for arsenic, tertiary butyl arsine (TBAs) of an organometallic gas is adopted, for example. As a source gas for phosphorus, tertiary butyl phosphine of an organometallic gas is adopted, for example.

In a ST22 step of stacking the p-type cladding layer 5 in the ST2 step, a semiconductor layer formed of, for example, p-type InP is stacked on the second main surface 42 of the active layer 4. In the ST22 step, trimethylindium of an organometallic gas is adopted as a source gas for indium, for example. As a source gas for phosphorus, tertiary butyl phosphine of an organometallic gas is adopted, for example. Further, zinc is adopted as an acceptor for generating majority carriers for example, and diethylzinc (DEZn) of an organometallic gas is adopted as a source gas for zinc for example. The first semiconductor layer 7 is fabricated by the steps up to and including ST22 step.

In a ST23 step of stacking the p-type contact layer 6 in the ST2 step, a p-type InGaAs layer is stacked as a semiconductor layer on the second main surface 52 of the p-type cladding layer 5. In the ST23 step, an organometallic gas is adopted as a raw material for each of indium, gallium, and arsenic. As a source gas for indium, for example, trimethylindium is adopted. Further, as a source gas for gallium, for example, triethylgallium is adopted. Further, as the source gas for arsenic, tertiary butyl arsine is adopted. Further, carbon is adopted as an acceptor for generating majority carriers, and for example, an organometallic gas of carbon tetrabromide (CBr₄) is adopted as a source gas for carbon.

In the ST23 step of stacking the p-type InGaAs layer as the p-type contact layer 6, the concentration of the doped carbon may be, for example, 1.0×10²⁰ cm⁻³ or more, and may further be 5.0×10²⁰ cm⁻³ or more.

In the ST23 step, the temperature of the substrate 2 is set to 500° C. or less. That is, the substrate 2 is heated at 500° C. or less by the heater. The temperature of the substrate 2 may be set to 300° C. to 500° C., and may further be set to 350° C. to 450° C.

Next, in the ST3 step, the heat treatment for activating the doped impurities is performed on the n-type cladding layer 3, the active layer 4, the p-type cladding layer 5, and the p-type contact layer 6, which are the semiconductor layers 3 to 6 stacked on or above the substrate 2 in the ST2 step.

In the ST3 step, the temperature at which the semiconductor layers 3 to 6 are heated during the heat treatment is set to 500° C. or less. That is, the semiconductor layers 3 to 6 are heated at 500° C. or less in the furnace. The heating temperature during the heat treatment may be set to 300° C. to 500° C., and may further be set to 350° C. to 500° C. Further, the time of the heat treatment may be, for example, 10 minutes. The heat treatment is performed in an inert gas atmosphere. As the inert gas, for example, nitrogen gas or argon gas is adopted.

In the method of manufacturing the semiconductor layered body according to the present embodiment, the source gas for arsenic in the ST23 step of stacking the p-type InGaAs layer forming the p-type contact layer 6 is tertiary butyl arsine. Conventionally, arsine (AsH₃) has been adopted as a source gas for arsenic, but arsine is a compound of arsenic and hydrogen, and hydrogen is generated by thermal decomposition. When hydrogen is incorporated into the semiconductor during crystal growth of the p-type InGaAs layer, carbon as an impurity is inactivated by bonding with hydrogen, and thus carbon does not function as an acceptor. As a result, the carrier density of the p-type InGaAs layer becomes lower than the concentration of the doped carbon in the p-type InGaAs layer. In contrast, when the source gas for arsenic is tertiary butyl arsine, the tertiary butyl arsine is an organometallic compound and is unlikely to generate hydrogen by thermal decomposition, so that the inactivation of carbon is reduced. This can improve the activation ratio of carbon contained in the p-type InGaAs layer.

Further, in the method of manufacturing the semiconductor layered body according to the present embodiment, the temperature of the substrate 2 in the ST23 step of stacking the p-type InGaAs layer forming the p-type contact layer 6 is 500° C. or less. Since carbon as an impurity is an amphoteric element, it is necessary to perform crystal growth of the p-type InGaAs layer at a low temperature in order to dope carbon as an acceptor at a high concentration. Also, carbon tends to inactivate at a high temperature. Since the temperature of the substrate 2 during the crystal growth of the p-type InGaAs layer is as low as 500° C. or less, carbon is doped at a high concentration as an acceptor, and the inactivation of carbon is reduced.

Further, in the method of manufacturing the semiconductor layered body according to the present embodiment, the step ST3 of performing the heat treatment on the semiconductor layers 3 to 6 including the p-type contact layer 6 is performed in an inert gas atmosphere and at a temperature of 500° C. or less. By performing the heat treatment on semiconductor layers 3 to 6 in an inert gas atmosphere in which hydrogen does not exist, such as a nitrogen atmosphere, the influence of the inactivation of carbon doped in the p-type InGaAs layer is reduced. In addition, since carbon tends to be inactivated at a high temperature, the inactivation of carbon doped in the p-type InGaAs layer is reduced by setting the temperature during the heat treatment to a low temperature of 500° C. or less.

As described above, according to the method of manufacturing the semiconductor layered body of the present disclosure, the activation ratio of carbon contained in the p-type InGaAs layer forming the p-type contact layer 6 can be improved. Thus, the semiconductor layered body 1 including the p-type InGaAs layer having a low resistivity with an increased carrier density and an increased carrier concentration is provided. In addition, since the activation ratio of carbon contained in the p-type InGaAs layer is high and the amount of non-activated carbon is reduced, the semiconductor layered body 1 having the p-type InGaAs layer with high reliability is provided.

In the method of manufacturing the semiconductor layered body according to the present embodiment, the source gas for arsenic in the ST23 step of stacking the p-type InGaAs layer forming the p-type contact layer 6 is tertiary butyl arsine. In order to increase the doping amount of carbon, it is necessary to stack the p-type InGaAs layer at a low temperature, but when arsine is used as the source gas for arsenic, the p-type InGaAs layer having good crystallinity is not stacked at a low temperature of 500° C. or less. In contrast, when tertiary butyl arsine is used as the source gas for arsenic, the tertiary butyl arsine has a low decomposition temperature and is thermally decomposed at a low temperature of 500° C. or less. Thus, the p-type InGaAs layer can be grown with good crystallinity even at a low temperature of 500° C. or less, and a high-quality p-type InGaAs layer is stacked by low-temperature crystal growth.

In the method of manufacturing the semiconductor layered body according to the present embodiment, a semiconductor layer whose conductivity type is n-type is not stacked on the p-type InGaAs layer forming the p-type contact layer 6. When the n-type semiconductor layer is stacked on the p-type InGaAs layer by epitaxial growth, it is necessary to raise the temperature to more than 500° C. in order to dope silicon (Si) or the like as a donor. However, at a high temperature exceeding 500° C., carbon contained in the p-type InGaAs layer is easily inactivated. According to the method of manufacturing the semiconductor layered body of the present embodiment, since the n-type semiconductor layer is not stacked on the p-type InGaAs layer, the inactivation of carbon contained in the p-type InGaAs layer is reduced.

In the semiconductor layered body 1, the p-type InGaAs layer forming the p-type contact layer 6 does not need to be the outermost surface. A cap layer formed of a III-V compound semiconductor such as InP may be stacked on the p-type InGaAs layer.

In the method of manufacturing the semiconductor layered body according to the present embodiment, the p-type InGaAs layer is not heated to a temperature exceeding 500° C. in the ST23 step for stacking the p-type InGaAs layer forming the p-type contact layer 6 and the ST3 step after the ST23 step. That is, in and after the ST23 step of stacking the p-type InGaAs layer, the temperature to which the p-type InGaAs layer is heated is 500° C. or less. According to the method of manufacturing the semiconductor layered body according to the present embodiment, the p-type InGaAs layer is not heated to a temperature exceeding 500° C., and thus, the inactivation of carbon contained in the p-type InGaAs layer is reduced.

### (Description of Structure of Light Emitting Element Using Semiconductor Layered Body)

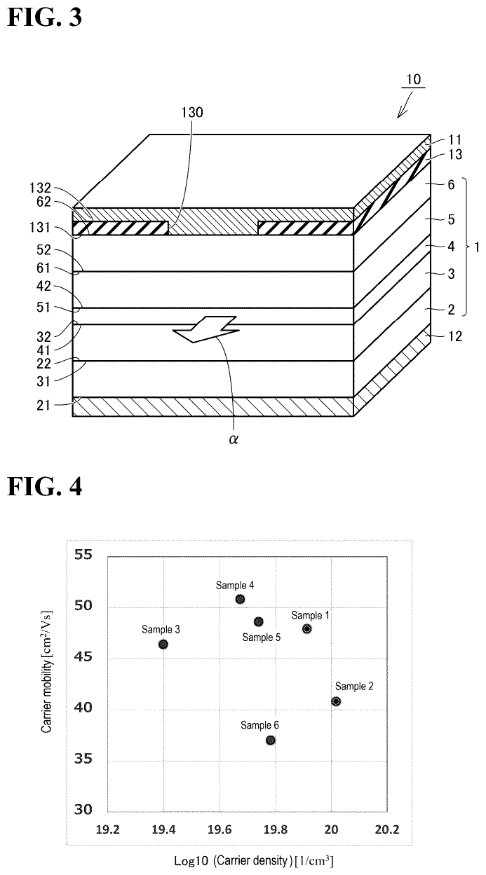

Next, a semiconductor laser 10, which is a light emitting element, will be described as an example of an optical semiconductor device that can be fabricated using the semiconductor layered body 1 according to the present embodiment, with reference to FIG. 3. FIG. 3 is a schematic diagram schematically showing a structure of the semiconductor laser 10 that is an optical semiconductor device according to an embodiment. The semiconductor laser 10 according to the present embodiment is fabricated using the semiconductor layered body 1 according to the present embodiment described above, and includes the substrate 2, the n-type cladding layer 3, the active layer 4, the p-type cladding layer 5, and the p-type contact layer 6. The semiconductor laser 10 further includes the first electrode 11 serving as an anode, a second electrode 12 serving as a cathode, and an insulating film 13. The semiconductor laser 10 is not particularly limited, but is, for example, an edge-emitting laser diode having a Fabry-Perot structure.

The insulating film 13 is formed of an insulator such as silicon nitride or silicon oxide. The insulating film 13 may be formed by using, for example, chemical vapor deposition.

The insulating film 13 has a pair of main surfaces, a first main surface 131 and a second main surface 132, which are parallel to each other and located at both ends in the film thickness direction. The film thickness of the insulating film 13 may be, for example, 0.1 μm to 100 μm. The insulating film 13 is disposed such that the first main surface 131 is in contact with the second main surface 62 of the p-type contact layer 6. The insulating film 13 has an opening 130 formed therein, which penetrates the insulating film 13 in the thickness direction.

The first electrode 11 is disposed so as to be in contact with the second main surface 132 of the insulating film 13. The first electrode 11 is formed of a conductor such as metal. For example, the first electrode 11 may be formed of a metal layer in which a titanium (Ti) layer, a platinum (Pt) layer, and a gold (Au) layer are stacked in this order. The first electrode 11 is filled in the opening 130 formed in the insulating film 13. As a result, the first electrode 11 is in contact with the second main surface 62 of the p-type contact layer 6 exposed in the opening 130.

The first electrode 11 can be formed, for example, as follows. First, a mask having an opening on a region where the opening 130 of the insulating film 13 is to be formed is formed on the insulating film 13. Then, after the opening 130 is formed in the insulating film 13 using the mask, the first electrode 11 formed of an appropriate conductor is formed by, for example, an evaporation method.

The second electrode 12 is disposed so as to be in contact with the first main surface 21 of the substrate 2. The second electrode 12 is formed of a conductor such as metal. For example, the second electrode 12 may be formed of a metal layer in which a titanium layer, a platinum layer, and a gold layer are stacked in this order. The second electrode 12 may be formed on the first main surface 21 of the substrate 2 by, for example, an evaporation method.

When a voltage is applied between the first electrode 11 and the second electrode 12, current flows between the first electrode 11 and the second electrode 12. At this time, holes are injected into the active layer 4 from the first electrode 11 and electrons are injected into the active layer 4 from the second electrode 12. Then, the holes and the electrons are recombined in the active layer 4, and light is generated. The generated light is confined in the active layer 4 sandwiched between the n-type cladding layer 3 and the p-type cladding layer 5 in the film thickness direction of the active layer 4. This light is repeatedly reflected between the end faces of the active layer 4. As a result, the light having the same phase is amplified, and laser oscillation is achieved. Then, the laser light is emitted along an arrow a.

The semiconductor laser 10 according to the present embodiment includes the semiconductor layered body 1 according to the present embodiment. Thus, according to the present disclosure, the semiconductor laser 10 having a low contact resistance is provided.

### Description of Modification

In the above-described embodiments, the semiconductor laser (laser diode) is exemplified as the optical semiconductor device of the present disclosure, and the semiconductor layered body suitable for fabricating the semiconductor laser is shown. The optical semiconductor device of the present disclosure is not limited to the semiconductor laser. The optical semiconductor device of the present disclosure may be, for example, a light emitting diode (LED) or a solar cell.

The semiconductor layered body of the present disclosure is not necessarily suitable for the fabrication of the optical semiconductor device, and can be widely applied to semiconductor devices that require a reduction in contact resistance of a p-type contact layer with respect to an electrode serving as an anode. In the semiconductor layered body of the present disclosure, as long as the p-type InGaAs layer of the present disclosure is adopted as the p-type contact layer, the layer structure, shape, and the like of the first semiconductor layer can be appropriately changed according to the semiconductor device to be applied. In addition, in order to form a tunnel junction region with a reduced operating voltage in a pn junction in which a p-type semiconductor layer and an n-type semiconductor layer are bonded, a semiconductor layer having a high carrier density is required. The semiconductor layered body of the present disclosure can be widely applied to semiconductor devices using tunnel junctions. In the semiconductor layered body of the present disclosure, as long as the p-type InGaAs layer of the present disclosure is adopted as a high-density p-type semiconductor having a high carrier density, the layer structure, shape, and the like of the first semiconductor layer can be appropriately changed according to the semiconductor device to be applied.

### EXAMPLES

The relationship between resistivity and carrier density and carrier mobility was investigated for the p-type InGaAs layer of the present disclosure. Procedures of the investigation are as follows. The resistivity of the p-type InGaAs layer was measured by a four-probe method using the van der Pauw method after Ti/Au electrodes were evaporated on the sample. The carrier density of the p-type InGaAs layer was measured by Hall measurement. The carrier mobility of the p-type InGaAs layer was determined from the measured resistivity and carrier density using a calculation formula (elementary charge x carrier density×carrier mobility×resistivity=1).

First, Sample 1 and Sample 2 were fabricated by the following method. Specifically, an InGaAs layer was stacked by growing InGaAs, which was undoped with an impurity, on a semi-insulating substrate formed of InP doped with iron (Fe) as an impurity, using metal organic chemical vapor deposition. The film thickness of the substrate was 350 nm. The film thickness of the InGaAs layer was 150 nm.

Then, the p-type InGaAs layer was stacked on the III-V compound semiconductor layer formed of the semi-insulating substrate and the InGaAs layer by growing InGaAs doped with carbon as an impurity using metal organic chemical vapor deposition. Carbon tetrabromide was used as a source gas for carbon. The concentration of the doped carbon was 1.4×10²⁰/cm³. Trimethylindium was used as a source gas for indium. Triethylgallium was used as a source gas for gallium. Tertiary butyl arsine was used as a source gas for arsenic. The temperature of the substrate when the p-type InGaAs layer was stacked was 400° C.

Then, a heat treatment was performed on the semiconductor layered body in which a p-type InGaAs layer was stacked on the III-V compound semiconductor layer. The atmosphere, temperature, time, and pressure of the heat treatment in Sample 1 were a nitrogen atmosphere, 450° C., 10 minutes, and 100 kPa, respectively. The atmosphere, temperature, time, and pressure of the heat treatment in Sample 2 were a nitrogen atmosphere, 475° C., 10 minutes, and 100 kPa, respectively.

Table 1 shows the results of measuring the resistivity, carrier density, carrier mobility, and carbon activation ratio of the p-type InGaAs layer of each of Sample 1 and Sample 2. Further, FIG. 4 shows a graph in which the horizontal axis represents the carrier density of the p-type InGaAs layer and the vertical axis represents the carrier mobility for each of Sample 1 and Sample 2.

As Samples 3 to 6 for comparison with Sample 1 and Sample 2, the semiconductor layered body described in Non-patent literature 1 is given. In the samples 3 to 6, the p-type InGaAs layer is stacked on a III-V compound semiconductor layer formed of InP by growing InGaAs doped with carbon as an impurity using metal organic chemical vapor deposition.

In the Samples 3 to 6, carbon tetrachloride is used as a source gas for carbon. The flow rates of carbon tetrachloride used for doping were 1 sccm for Sample 3, 4 sccm for Sample 4, 7 sccm for Sample 5, and 10 sccm for Sample 6, as read from data plotted in the graph shown in Non-patent literature 1. Trimethylindium is used as a source gas for indium. Triethylgallium is used as a source gas for gallium. Arsine is used as a source gas for arsenic. The temperature of the substrate when the p-type InGaAs layer is stacked is 430° C. The atmosphere, temperature, and time of the heat treatment in Samples 3 to 6 are an argon gas atmosphere, 600° C., and ⅙ minute, respectively.

Table 1 shows the results read from data plotted in the graph shown in Non-patent literature 1 with respect to the resistivity, carrier density, and carrier mobility of the p-type InGaAs layer of each of Samples 3 to 6. Further, FIG. 4 shows a graph in which the horizontal axis represents the carrier density of the p-type InGaAs layer and the vertical axis represents the carrier mobility for each of Samples 3 to 6. According to Non-patent literature 1, the activation ratio of carbon in the Sample 3 is 83.3%.

TABLE 1

| | | Carrier | Log10 | Carrier | Activation |
|---|---|---|---|---|---|
| | Resistivity | density | (Carrier | mobility | ratio |
| | (Ωcm) | (1/cm³) | density) | (cm²/Vs) | (%) |
| Sample 1 | 0.00159 | 8.19e+19 | 19.9 | 48.0 | 58.5 |
| Sample 2 | 0.00147 | 1.04e+20 | 20.1 | 40.8 | 74.3 |
| Sample 3 | 0.00537 | 2.51e+19 | 19.4 | 46.4 | 83.3 |
| Sample 4 | 0.00260 | 4.72e+19 | 19.67 | 50.8 | — |
| Sample 5 | 0.00233 | 5.50e+19 | 19.74 | 48.6 | — |
| Sample 6 | 0.00260 | 6.5e+19 | 19.8 | 37.0 | — |

As can be seen from Table 1 and FIG. 4, it was confirmed that the semiconductor layered bodies of Sample 1 and Sample 2 each including the p-type InGaAs layer having a resistivity of 2.0×10⁻³ Ωcm or less had a higher carrier density and a higher carrier mobility in the p-type InGaAs layer than the semiconductor layered bodies of Sample 3 to Sample 6 each including the p-type InGaAs layer having a resistivity exceeding 2.0×10⁻³ Ωcm.

It should be understood that the embodiments and examples disclosed herein are illustrative in all respects and are not restrictive in any aspect. The scope of the present invention is defined not by the above description but by the scope of the claims, and is intended to include all modifications within the meaning and scope equivalent to the scope of the claims.

What is claimed is:

1. A semiconductor layered body comprising:
a first semiconductor layer formed of a III-V compound semiconductor; and
a p-type InGaAs layer stacked on the first semiconductor layer and containing carbon as an impurity that generates majority carriers,
wherein the p-type InGaAs layer has a resistivity of 2.0×10⁻³ Ωcm or less.

2. The semiconductor layered body according to claim 1,
wherein a mobility of the majority carriers in the p-type InGaAs layer is 40 cm²/Vs or more.

3. The semiconductor layered body according to claim 1,
wherein a density of the majority carriers in the p-type InGaAs layer is 8.0×10¹⁹ cm⁻³ or more.

4. The semiconductor layered body according to claim 1,
wherein an activation ratio of the impurity in the p-type InGaAs layer is 50% or more.

5. An optical semiconductor device comprising:
a semiconductor layered body including a first semiconductor layer formed of a III-V compound semiconductor and a p-type InGaAs layer stacked on the first semiconductor layer, the p-type InGaAs layer containing carbon as an impurity that generates majority carriers, the p-type InGaAs layer having a resistivity of 2.0×10⁻³ Ωcm or less; and
an electrode disposed in contact with the p-type InGaAs layer of the semiconductor layered body.

6. A method of manufacturing a semiconductor layered body, the method comprising:
preparing a substrate formed of a III-V compound semiconductor:
stacking a semiconductor layer formed of a III-V compound semiconductor on the substrate by epitaxial growth; and
performing heat treatment on the semiconductor layer,
wherein the stacking the semiconductor layer includes stacking a p-type InGaAs layer containing carbon as an impurity that generates majority carriers by a chemical vapor deposition using an organometallic gas as a raw material for each of indium, gallium, and arsenic,
wherein, in the stacking the p-type InGaAs layer, the raw material for arsenic is tertiary butyl arsine, and a temperature of the substrate is 500° C. or less, and
wherein, in the performing the heat treatment on the semiconductor layer, the semiconductor layer is heated at a temperature of 500° C. or less in an inert gas atmosphere.
